(19) United States
(12) Patent Application Publication
(10) Pub. No.: US 2024/0413054 A1
(43) Pub. Date: Dec. 12, 2024

(54) INTEGRATED CIRCUIT PACKAGES WITH FLUID SPACERS TO IMPROVE PIN LOAD DISTRIBUTION

(71) Applicant: Intel Corporation, Santa Clara, CA (US)

(72) Inventors: Min Pei, Camas, WA (US); Ralph V. Miele, Hillsboro, OR (US); Lejie Liu, Portland, OR (US); Phil Geng, Washougal, WA (US); Caleb Million Tessema, Portland, OR (US)

(73) Assignee: Intel Corporation, Santa Clara, CA (US)

(21) Appl. No.: 18/810,136

(22) Filed: Aug. 20, 2024

(51) Int. Cl. H01L 23/467; H01L 23/367; H01L 23/40

(52) U.S. Cl. CPC H01L 23/467; H01L 23/3677; H01L 23/4093

(57) ABSTRACT

Integrated circuit packages with fluid spacers to improve pin load distribution are disclosed. An example apparatus includes an integrated circuit (IC) package, a circuit board, a socket to couple the IC package and the circuit board, a backplate coupled to the circuit board, a loading assembly to provide a stack load to the IC package, and a fluid liner positioned between the circuit board and the backplate.

### BACKGROUND

The demand for greater computing power and faster computing times continues to grow. This has led to higher density connectors on computer hardware components to transfer signals more quickly. Some processor chips (e.g., land grid array (LGA) processor chip, ball grid array (BGA) processor chip, etc.) are communicatively coupled to printed circuit boards (PCBs) via sockets constructed to receive and electrically couple to contacts on the processor chips.

### BRIEF DESCRIPTION OF THE DRAWINGS

FIG. 1 is an exploded view of an example integrated circuit (IC) package component stack in accordance with teachings disclosed herein.

FIG. 2A a simplified, cross-sectional view of the example component stack of FIG. 1 prior to an example heatsink being pressed down onto an example IC package.

FIG. 2B is another simplified, cross-sectional view of the example components of FIG. 2A after the example heatsink has been pressed down onto the example IC package.

FIG. 3A is a perspective top view of an example fluid spacer of the example IC package of FIGS. 1, 2A and 2B.

FIG. 3B is a cross-sectional view of the example fluid spacer of FIG. 3A.

FIG. 4 is a cross-sectional view of another example fluid spacer disclosed herein that may be included in an IC package.

FIG. 5 is a cross-sectional view of yet another example fluid spacer disclosed herein that may be included in an IC package.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

As the computing industry evolves, the demand for higher input/output (IO) speeds and throughput continues to increase. Computer hardware components, such as central processing units (CPUs), graphical processing units (GPUs), memory, motherboards, etc., are often connected by electrical connectors. For example, a CPU in a server system may be connected to one or more other components by a cable connector that connects to a mating connector on a substrate or board of the CPU. A recent trend has been to increase the IO capability by adding more pin counts to the connectors on the CPUs. However, traditional cable connectors use two rows of pins, which are relatively low density. As a result, adding more pins to the cable connector requires more space on the board and therefore increases the overall size of the package. In some instances, there may not be enough space to add more pins. Manufacturers desire to keep the package size small while still increasing the IO capabilities.

Socket-based architectures include a socket substrate for receiving a socket-based package (e.g., hereinafter an integrated circuit (IC) package). Socket-based architectures include a socket substrate having pins to contact pads on a surface of an opposing socket-based package or IC package (e.g., a land grid array (LGA) package). Socket-based architectures, including LGA packages, provide higher land counts, thereby improving the IO capability of a system. The socket pins are relatively thin and can be placed in a high-density arrangement.

Typically, a compression or loading mechanism provides a stack load to deflect pins of a socket against corresponding opposing pads of an IC package with sufficient force (e.g., at least 0.022046 pound-force (lb-f) (10 grams-force) per pin) to ensure consistent and reliable electrical contact between the components (e.g., pins and pads). In some examples, the amount of force and/or the deflection force per pin can be based on a design of the contact pads and/or pins (e.g., a pin load of 10 grams-force per pin, a pin load greater than 10 grams-force per pin, or a pin load of less than 10 grams-force per pin). However, providing a greater pin density requires increased compression forces to compensate for the increased number of pins. As a result, a greater stack load (e.g., compression load) is needed to increase a pin load across a pin array to provide a reliable connection (e.g., a pin load of at least 10 gram-force per pin) when increasing a number of pins to provide greater IO capabilities.

Typically, an example loading mechanism includes a plurality of fasteners spaced along a perimeter of the socket assembly. However, distribution of a stack load provided by a loading mechanism is not uniform between a perimeter edge of the IC package and/or circuit board and a center of the IC package and/or circuit board and/or a backplate. For example, an IC package having a 10,000 pin count and a compression loading mechanism providing 10 grams of force per pin would require a stack load of approximately 220 pound-force (lb-f) (100,000 gram-force) if a stack loading provided by the loading mechanism is uniformly distributed across the pin array. However, stack loading is not uniform due to package warpage, backplate warpage and/or heatsink warpage. Due to warpage, loading each pin with at least 10 gram force (g-f) in a pin array of 10,000 pins can require a stack load of greater than 1000 pound-force (lb-f) (454,000 gram-force), which is 5 times greater than needed if the force distribution was uniformly distributed across the pin array. Thus, to achieve desired pin loading near or at a center of an IC package and/or circuit board results in a greater amount of force (e.g., stack load) needed along a perimeter of the IC package and/or circuit board. However, applying a greater amount of force to the perimeter of the IC package and/or circuit board can lead to warpage and/or deformation of the IC package, a backplate of the component stack, and/or a heatsink of the component stack. As a result, backplate warpage can reduce a performance of the IC package due to the reduced contact between the IC package and the printed circuit board. Additionally, in some examples, if a socket substrate is subject to vibrations (e.g., during shipping, during vibrational testing, etc.), the pins of the socket may move (e.g., slide) relative to the pads of an IC package. In such examples, the pins may scratch and/or damage the opposing pads (e.g., via fretting) which, in turn, wears down coatings on the pads that prevent oxidation. When the coatings are scratched away, the underlying material of the contact pads (e.g., nickel, copper, etc.) is exposed to environmental conditions (e.g., moisture, air, etc.). The underlying material can oxidize, which may reduce the electrical conductivity between the pins and associated pads. In some examples, warpage can lead to pin load reduction, which can cause fretting on pad surfaces of an associated IC package due to vibration caused by tilting of a thermal mass due to side loads.

To restrict warpage of the package, socket-based packages typically include packages, backplates and/or heatsinks with increased stiffness characteristics and/or thicknesses. However, increasing the stiffness of the package, the backplate and/or the heatsink increases an overall stack height. Some socket-based packages employ relatively high modulus materials (e.g., ceramic) to increase stiffness, but such materials significantly increase costs and/or may be prone to damage (e.g., cracking). Some socket-based packages employ an insulator material or pre-shaped backplate to compensate for warpage. However, insulator material(s) and/or pre-shaped backplates typically have a thickness of approximately between 100 to 200 micrometers (μm), which leads to difficulty in tolerance control, and thereby increases manufacturing complexities and/or costs. Additionally, package thickness is also difficult to control because a thickness difference of a package from center to edge can vary by approximately 300 micrometers (μm). Moreover, the insulator and/or pre-shaped backplate cannot cover different designs or variations (e.g., corner designs) of a package assembly.

Examples disclosed herein improve pin contact between the sockets of printed circuit boards and the associated IC packages. Specifically, examples disclosed herein provide fluid-filled structures (e.g., fluid spacers, fluid-filled bladders, fluid-filled liners, fluid-filled pockets, etc.) for use in socket-based architectures to improve stack load distribution across pins (e.g., a pin array) of a socket/package interface. In other words, fluid-filled structures disclosed herein improve stack load distribution between perimeter edges of a socket-based package or circuit board and a center of socket-based package or circuit board.

Some examples disclosed herein provide fluid-filled structures (e.g., fluid bags, fluid pockets, etc.) between a backplate and a printed circuit board (PCB) of a component stack to distribute a stack load more evenly or uniformly across pins or pads of an integrated circuit (IC) package assembly. As a result of providing greater pin load uniformity across the pins of the IC package, a total stack load needed to load each pin at a desired pin load can be significantly reduced. Additionally, a backplate stiffness requirement is reduced when improved uniform force distribution of a stack load is applied to the IC package. Moreover, backplate warpage is reduced, thereby enabling use of a backplate with a smaller thickness than conventional backplates. In other words, distributing a stack load of a socket-based structure and/or across a backplate, circuit board and/or IC package more evenly reduces an amount of force needed to compress pads and/or pins of an IC package and socket interface using a desired and/or target pin load. As a result of distributing a stack load across the interface more evenly with example fluid-filled structures disclosed herein, component warpage concerns are reduced. Examples disclosed herein can reduce stack component warpage by approximately between 50 micrometers (μm) and 200 micrometers (μm) (e.g., 100 micrometers (μm)).

Moreover, providing a more uniform force distribution across the IC package and/or a pin/pad array reduces instances of fretting. For example, fluid within example fluid-filled structures disclosed herein provide pressure to compensate for areas of low pin load, which reduces pin vertical movement. Furthermore, example fluid-filled structures can function as a dampener that absorbs vibrations while maintaining relatively constant pin loads. If constant pressure and pin load are maintained under vibration load, pin fretting damage can be significantly reduced or eliminated. Additionally or alternatively, examples disclosed herein reduce and/or eliminate fretting on pad surfaces of an associated IC package due to vibration caused by tilting of thermal mass when a side load is applied because the fluid spacer (e.g., filled with a low viscous fluid) provides pressure (e.g., reactive forces) to compensate low pin loads and reduce pin vertical movement. If constant pressure and pin load are maintained under vibration load, pin fretting damage can be reduced or eliminated.

Example fluid-filled structures disclosed herein can include, but are not limited to, a fluid filled liner or bag (e.g., a hermetically sealed bag or liner), a fluid-filled spacer, a fluid-filled pocket formed on a backplate, a fluid-filled bladder and/or any other fluid-filled device or structure that can be positioned between a backplate and a circuit board of a stacked component assembly. In some examples, a fluid-filled structure can include a plurality of compartmentalized fluid chambers that can include different types of fluids. Additionally, as used herein a “fluid” can include, but is not limited to, a gas, a liquid, a slurry solution, a low viscous fluid, a dielectric material, a non-electrically conductive fluid, any combination thereof, and/or any other fluid(s). In some examples, the fluid can include, but is not limited to, air, water, an inert gas, wax, a gel, a dielectric fluid (e.g., a dielectric liquid or dielectric gas), a combination thereof, and/or any other fluid(s). Additionally, a fluid-filled structure (e.g., a liner) disclosed herein can be made of, but is not limited to, polyethylene terephthalate (PET), metalized polyethylene terephthalate (MET-PET), polyethylene (PE), a dielectric material, a combination thereof, and/or any other suitable material(s).

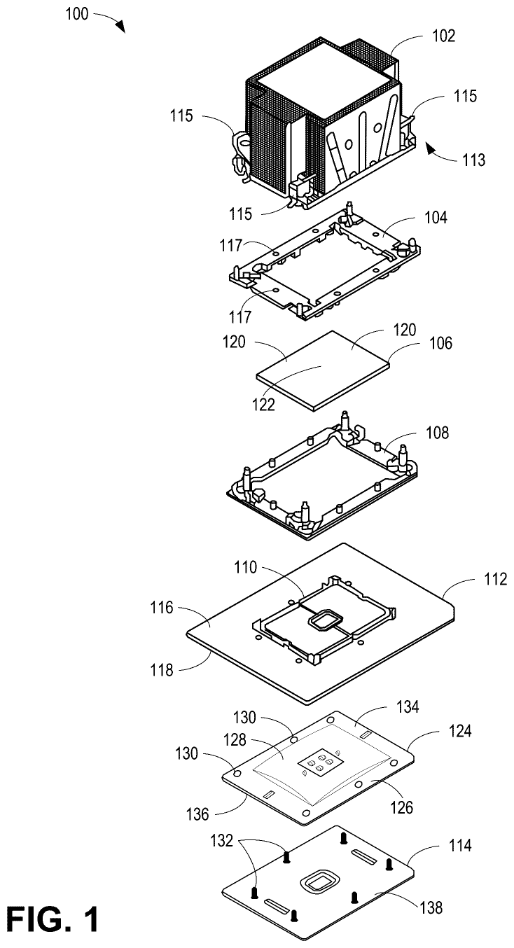

FIG. 1 illustrates an exploded view of an example component stack 100 (e.g., an integrated circuit (IC) package component stack) constructed in accordance with teachings disclosed herein. In FIG. 1, the component stack 100 includes a heatsink 102, a carrier 104 (e.g., a package carrier, a carrier plate), an integrated circuit (IC) package 106, a bolster plate 108, a socket 110 coupled to a printed circuit board (PCB) 112 (e.g., a motherboard), and a backplate 114 (e.g., a frame, a metal plate, a fluid-filled structure, etc.).

In this example, the IC package 106 includes one or more electrical circuits on a semiconductor substrate. In some examples, the IC package 106 can perform processing functions, memory functions, and/or any other suitable functions. The IC package 106 can include any type of processing circuitry, including programmable microprocessors, one or more FPGAs, one or more CPUs, one or more GPUs, one or more DSPs, one or more XPUs, one or more ASICs, and/or one or more microcontrollers. In FIG. 1, the IC package 106 is a land grid array (LGA) processor chip. Additionally or alternatively, the IC package 106 can be one of a ball grid array (BGA) processor chip or a pin grid array (PGA) processor chip instead. Further, other types of IC packages can be used in the component stack 100 instead of a processor chip (e.g., a memory chip). In FIG. 1, the carrier 104 is used to couple the heatsink 102 to the IC package 106 prior to assembly of the component stack 100. In some examples, the carrier 104 is omitted and the assembly process involves inserting the IC package 106 into the socket 110 and then attaching the heatsink 102. In FIG. 1, the heatsink 102 is couplable (e.g., thermally couplable) to the IC package 106 to dissipate heat therefrom.

The socket 110 communicatively couples the IC package 106 to the PCB 112. In FIG. 1, the socket 110 is an LGA socket, which includes a plurality of pins within the socket arranged to interface (e.g., electrically couple) with corresponding contacts/lands/pads on the IC package 106. In other examples, the socket 110 can be implemented by any other type of socket (e.g., a BGA, a PGA, etc.) suitable to receive and interface with the IC package 106.

To provide a compression or stack load to couple the components in compression (e.g., to improve an electrical connection between the socket 110 and the IC package 106), the component stack 100 of the illustrated example includes a loading assembly 113 (e.g., a loading mechanism, a spring, a fastener, etc.). Thus, the loading assembly 113 imparts a load (e.g., a vertical or stack load) to the IC package 106. In the illustrated example, the loading assembly 113 includes the heatsink 102.

To provide a stack load, the heatsink 102 is mechanically coupled to the backplate 114 via fixture elements, loading mechanisms, or fasteners 115 to place the components between the heatsink 102 and the backplate 114 within the component stack 100 in compression when assembled. In some examples, the heatsink 102 is coupled to the backplate 114 via the bolster plate 108 positioned therebetween. More particularly, as shown in FIG. 1, the bolster plate 108 is couplable to an upper surface 116 of the PCB 112 while the backplate 114 is couplable to a lower surface 118 of the PCB 112 opposite the bolster plate 108. In this manner, the PCB 112 is sandwiched between the bolster plate 108 and the backplate 114. The bolster plate 108 is constructed to surround the socket 110 positioned on the upper surface 116 of the PCB 112. In the illustrated example, the compression created by the mechanical coupling of the heatsink 102 to the backplate 114 via the fasteners 115 serves to ensure that corresponding connectors (e.g., pins, lands, etc.) on the socket 110 and the IC package 106 remain in contact. In some examples, the loading assembly 113 can be provided by fasteners 117 of the carrier 104 and/or can be provided by any other loading mechanism(s) or fastener(s).

As noted previously, a force distribution across the contacts (e.g., land) of the IC package 106 is typically not uniform, thereby requiring a greater amount of stack load along the perimeter 120 of the IC package 106 than a center 122 of the IC package 106 to achieve a desired target load at the center 122 of the IC package 106.

In accordance with teachings disclosed herein, the example component stack 100 includes an example fluid spacer 124. The fluid spacer 124 is positioned on, carried by, and/or included with the component stack 100 to improve uniform stack loading distribution profile. The fluid spacer 124 of the illustrated example is positioned between the backplate 114 and the PCB 112. The fluid spacer 124 of the illustrated example includes a flange 126 and a fluid chamber 128 (e.g., a pocket). The flange 126 includes a plurality of apertures 130 to receive corresponding respective ones of guide pins 132 projecting from the backplate 114. When assembled, a first side 134 (e.g., a first or upper surface) of the fluid spacer 124 of the illustrated example is oriented toward the lower surface 118 of the PCB 112 and a second side 136 (e.g., a second or lower surface) opposite the first side 134 of the fluid spacer 124 of the illustrated example is oriented toward an upper surface 138 of the backplate 114. The fluid spacer 124 of the illustrated example has a shape complimentary to a shape of the PCB 112 and/or the backplate 114. For example, the fluid spacer 124 of the illustrated example has a rectangular shape. The flange 126 and/or the fluid chamber 128 of the illustrated example have rectangular shapes. However, in some examples, the fluid spacer 124 (e.g., the flange 126 and/or the fluid chamber 128) can have a square shape, a triangular shape, a circular shape, an oblong shape, and/or any other suitable shape(s). In some examples, the fluid spacer 124 can be coupled to the backplate 114 via adhesive, welding, and/or other fastener(s). In some examples, the fluid spacer 124 does not include the flange 126 and/or the apertures 130. In some examples, the fluid spacer 124 is positioned (e.g., entirely positioned) withing a perimeter of the guide pins 132.

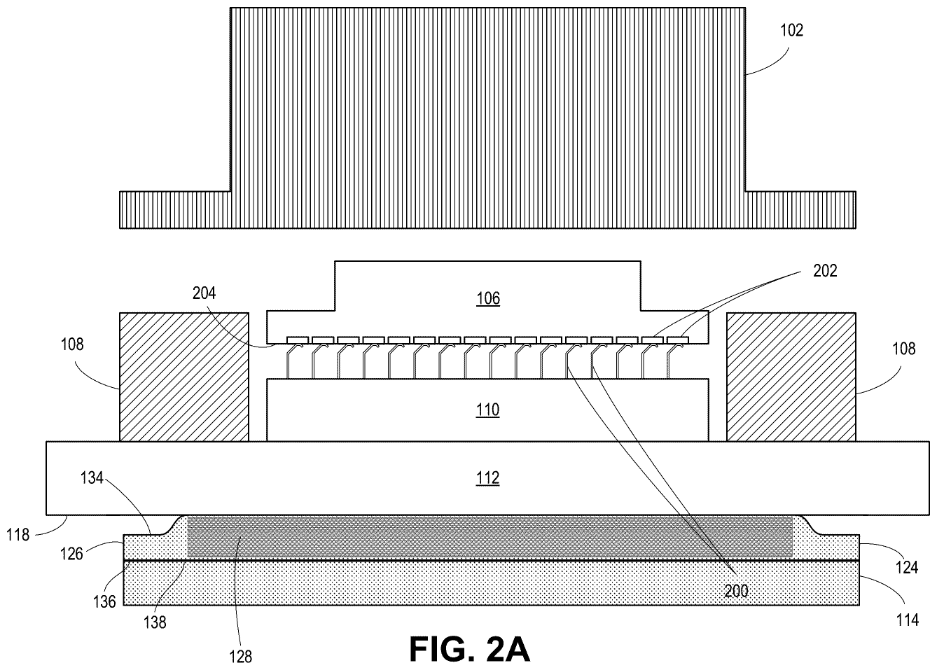

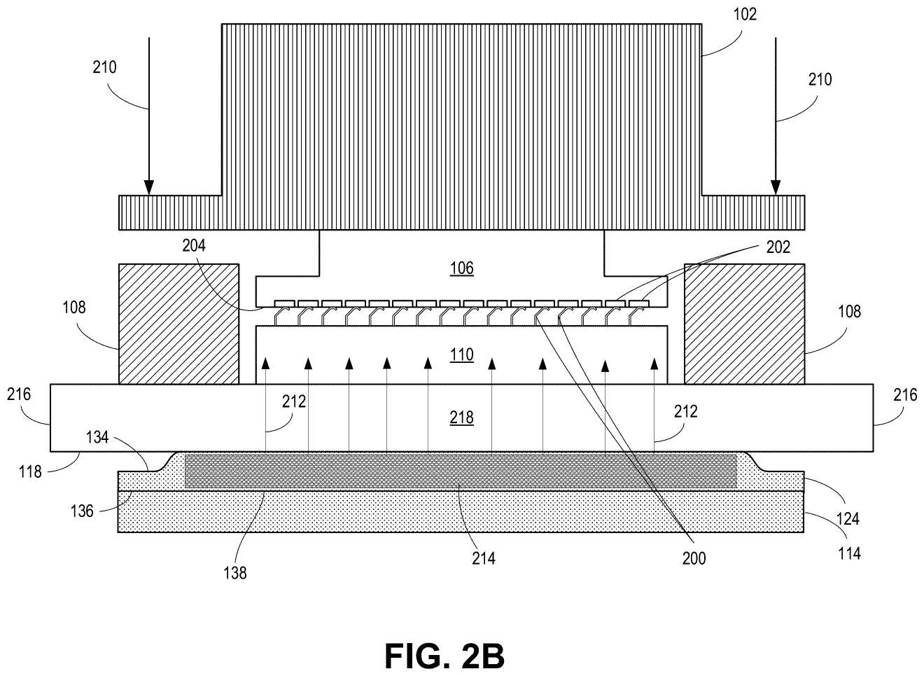

FIG. 2A is a simplified cross-sectional view of the example component stack 100 of FIG. 1 prior to the heatsink 102 being pressed down onto the example IC package 106. FIG. 2B is another simplified cross-sectional view of the component stack 100 of FIG. 1 after the example heatsink 102 has been pressed down onto the example IC package 106.

In FIGS. 2A and 2B, the component stack 100 includes the heatsink 102 of FIG. 1, the IC package 106 of FIG. 1, the bolster plate 108 of FIG. 1, the socket 110 of FIG. 1, the PCB 112 of FIG. 1, the backplate 114 of FIG. 1, and the fluid spacer 124 of FIG. 1 (the carrier 104 of FIG. 1 and the fasteners 115 of FIG. 1 are omitted in FIGS. 2A and 2B for clarity). Further, the example component stack 100 of FIGS. 2A and 2B illustrates example pins 200 (e.g., a pin array) of the socket 110 in contact with example pads 202 (e.g., a pad array) on the IC package 106. As such, an example surface 204 (e.g., bottom surface) of the IC package 106 can include a BGA or an LGA.

In FIG. 2A, the example heatsink 102 is shown separate (e.g., removed, disassembled, etc.) from the IC package 106. Alternatively, in FIG. 2B, the example heatsink 102 is shown coupled to (e.g., in contact with, thermally coupled with, etc.) the IC package 106. In particular, the example heatsink 102 thermally couples to an example semiconductor die included in the IC package 106. In some examples, the heatsink 102 thermally couples to such a semiconductor die via an integrated heat spreader (IHS) and/or any other structure or material. The fluid spacer 124 of the illustrated example is positioned (e.g., sandwiched) between the PCB 112 and the backplate 114. Specifically, when assembled, the PCB 112 engages (e.g., directly engages) the fluid chamber 128 of the fluid spacer 124. For example, the first side 134 (e.g., a first surface) of the fluid spacer 124 of the illustrated example engages (e.g., directly engages) the lower surface 118 of the PCB 112 and the second side 136 (e.g., opposite the first side 134) of the fluid spacer 124 of the illustrated example engages (e.g., directly engages) the upper surface 138 of the backplate 114. In the illustrated example, the fluid chamber 128 of the fluid spacer 124 aligns (e.g., vertically aligns) with the IC package 106 (e.g., the pads 202 of the IC package 106) and/or the socket 110 (e.g., the pins 200 of the socket 110). In other words, an area of the fluid spacer 124 (e.g., an area of fluid chamber 128) is greater than or substantially equal to an area of the IC package 106 (e.g., an area of the pad 202) and/or the socket 110 (e.g., defining an area of the pins 200). Thus, the fluid chamber 128 of the fluid spacer 124 has an area (e.g., a first area) that is greater than an area (e.g., a second area) of the pin array of the socket 110 and/or the pads of the IC package 106. Thus, the fluid chamber 128 of the illustrated example vertically aligns and/or covers (e.g., completely covers or overlaps) a socket interface (e.g., an interface provided by the pins 200 and the pads 202) of the component stack 100. In some examples, the fluid spacer 124 can have an area that is less than an area of the pin array of the socket 110 and/or the pads of the IC package 106.

Referring to FIG. 2B, when the heatsink 102 is coupled to the example component stack 100, the loading assembly 113 of FIG. 1 imparts a compressive force or a stack load 210 to the IC package 106 (e.g., a downward force in the orientation of FIG. 2B). The stack load 210 causes the IC package 106 to move or displace (e.g., in a downward direction) toward the pins 200 of the socket 110. As the IC package 106 moves toward the pins 200, the pins 200 deflect, thereby exerting a reactive force against the pads 202 to provide reliable electrical connection between the pads 202 and the pins 200. Additionally, the stack load 210 imparts forces or pressure differences between different portions of the backplate 114 and corresponding different portions of the PCB 112 and the fluid spacer 124.

The fluid chamber 128 of the illustrated example is deformable (e.g., elastically deformable), flexible and/or otherwise deflects to enable fluid 214 within the fluid chamber 128 to move in response to stack loads 210 imparted to the fluid spacer 124 and the associated warpage in the PCB 112 resulting from the stack loads 210. Additionally, the fluid chamber 128 is a fixed volume chamber. Thus, when pressure is applied to a confined fluid (e.g., liquid or gas) in response to the stack load 210 imparted to the component stack 100 (e.g., the fluid spacer 124), the applied pressure is transmitted substantially undiminished throughout the fluid 214 in all directions (e.g., across an area of the fluid chamber 128). In other words, any force applied to one part of the fluid 214 is distributed substantially equally to all other parts of the fluid 214 within the fluid chamber 128. Thus, because the fluid chamber 128 is flexible, the fluid 214 is displaceable or moveable within the fluid spacer 124 in response to the stack load 210. Thus, the fluid 214 within the fluid chamber 128 moves within the fluid spacer 124 in response to pressure differences between different portions of the backplate 114 and corresponding different portions of the PCB 112.

As a result, the fluid 214 inside the fluid chamber 128 provides a pin load 212 (e.g., reactive force(s)) toward the pins 200 and/or the pads 202. In other words, the fluid spacer 124 distributes a pin load (e.g., a uniform or even load) across the pins 200 and/or the pads 202. Specifically, the fluid 214 can move from a high force area adjacent the perimeter 120 of the IC package 106 and/or a perimeter 216 of the PCB 112 to a low force area adjacent the center 122 of the IC package 106 and/or the center 218 of the PCB 112. In other words, the fluid chamber 128 can move a high force area to a low force area to help evenly distribute the pin load 212 across the pin array (e.g., the pins 200) and/or the PCB 112.

As a result, the fluid spacer 124 distributes the stack load 210 (e.g., evenly, or substantially evenly) across an area of the IC package 106. The fluid spacer 124 distributes a pin load 212 to the pins 200 and/or the pads 202 (e.g., the pin/pad interface or array). In contrast to known component stacks, the component stack 100 of the illustrated example provides a more even distribution of the pin load 212 across the pins 200 (e.g., a pin array or area) of the socket 110 and/or the pads 202 of the IC package 106. Specifically, the fluid spacer 124 reacts to the stack load 210 and/or distributes the stack load 210 to provide the pin load 212 (e.g., a pressure) that is substantially evenly or uniformly distributed across the pins 200 (e.g., a pin array or area) of the socket 110 and/or the pads 202 (e.g., a pad array and/or area) of the IC package 106. Specifically, the fluid 214 moves within the fluid chamber 128 to help distribute the stack load 210 evenly and/or uniformly across the pins 200 and/or the pads 202. In this manner, the fluid 214 distributes the stack load 210 from a perimeter 216 (e.g., or adjacent an outermost perimeter edge) of the PCB 112 toward a center 218 of the PCB 112. More specifically, the fluid 214 distributes the pin load 212 (e.g., a reactive load) evenly across the PCB 112 between the perimeter 216 (e.g., perimeter edges) and the center 218 of the PCB 112 in response to pressures imparted to the PCB 112 and/or the backplate 114 via the stack load 210 provided by the loading assembly 113. As used herein, substantially evenly or uniformly means that the reactive force or pressure across the pins between the perimeter 216 and the center 218 of the PCB 112 and/or the pins 200 or pads 202 is substantially equal or even (e.g., and/or within a small delta). In some examples, a substantially even or uniform force can be a smaller variance than without using a fluid spacer 124. In some examples, substantially even or uniform force can be a difference of approximately between 0.1 gram-force and 5 gram-force.

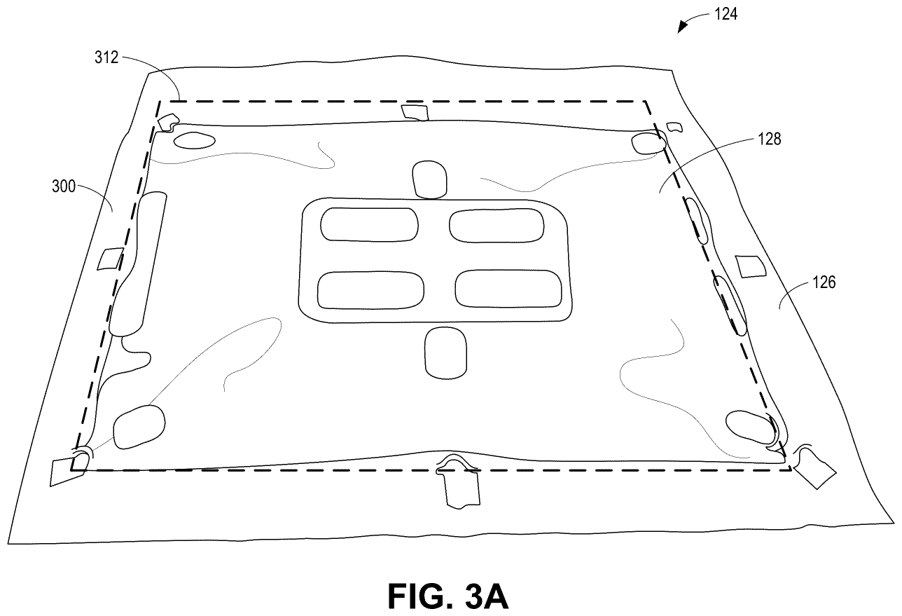

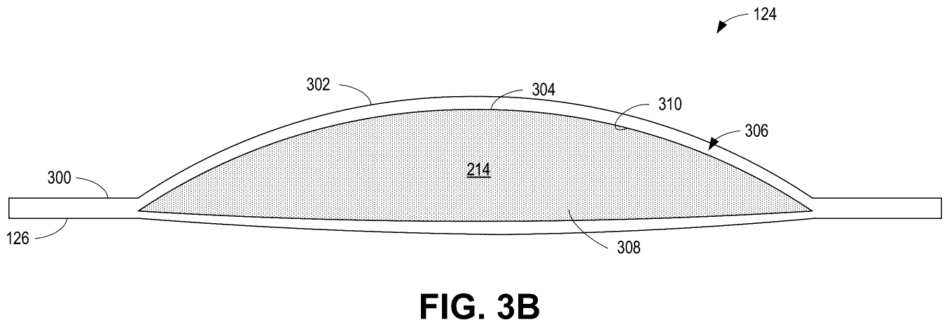

FIG. 3A is a perspective view of the example fluid spacer 124 of FIGS. 1, 2A and 2B. FIG. 3B is a cross-sectional view of the example fluid spacer 124 of FIG. 3A. The fluid spacer 124 of the illustrated example is a fluid-filled structure. The fluid spacer 124 of the illustrated example includes a liner 300 defining the flange 126 and the fluid chamber 128. Specifically, the liner 300 of the illustrated example includes a first liner 302 and a second liner 304. However, in some examples, the liner 300 can be a single sheet of material and/or can be a plurality of sheets of material (e.g., greater than two sheets). The second liner 304 of the illustrated example is located within a cavity 306 (e.g., a pocket) provided by the first liner 302. The second liner 304 defines the fluid chamber 128. The first liner 302 and/or the second liner 304 are hermetically sealed. In this manner, the second liner 304 and/or the fluid chamber 128 provides a fixed volume chamber 308 to retain the fluid 214. In the illustrated example, the first liner 302 and the second liner 304 can be two or more sheets of plastic or treated fabric that can be joined (e.g., via sewing, welding, adhesive, etc.) to define the fluid chamber 128 (e.g., a pocket) that can carry or contain the fluid 214. The first liner 302 and/or the second liner 304 (e.g., one or more walls or surfaces 310) defining the fluid chamber 128 are at least one of flexible or deformable. Thus, the fluid chamber 128 and/or the liner 300 of the illustrated example provides a fluid bladder or balloon, which can be positioned between the PCB 112 and the backplate 114. An area 312 of the fluid chamber 128 (e.g., flexible chamber) is greater than an area of the pins 200 and/or the pads 202 (e.g., a pin/pad array) of the socket 110 and IC package 106. In the illustrated example, the fluid bladder is to deform in response to pressure variations across the PCB 112 and/or the backplate 114. For example, although the fluid chamber 128 of the illustrated example is a fixed volume chamber, the fluid chamber 128 (e.g., the surfaces defining the fluid chamber 128) is formed of a flexible or deformable material (e.g., elastically deformable material) and, thus, can deflect, deform and/or otherwise allow the fluid chamber 128 to move within the enclosed or fixed volume of the fluid chamber 128 in response to a force imparted to the fluid chamber 128.

The liner 300 (e.g., the first liner 302 and/or the second liner 304) of the illustrated example can be composed of high strength polymer sheets fused together to form a pocket and/or flexible chamber (e.g., a pouch). In some examples, a dielectric material can be used to form the fluid chamber 128 and/or the liner 300 (e.g., the first liner 302 and/or the second liner 304). In some examples, the first liner 302 can be a different material compared to the second liner 304. For example, the second liner 304 can include a dielectric material and the first liner 302 can include a polymer material. In some examples, the second liner 304 can include a polymer material and the first liner 302 can include a dielectric material. In this manner, the dielectric material provides an insulation layer. The fluid spacer 124 (e.g., the liner 300, the first liner 302 and/or the second liner 304) can include, but is not limited to, polyethylene terephthalate (PET), metalized polyethylene terephthalate (MET-PET), polyethylene (PE), vinyl, polyethylene, polyvinyl chloride (PVC), Low-Density Polyethylene (LDPE), Polypropylene (PP), rubber, foil, flexible plastic materials, dielectric material(s), a combination thereof, and/or any other suitable material(s). In some examples, the liner 300 can include, for example, a barrier material that provides an effective barrier against gas and/or liquid permeation. Some example barrier materials include glass, metal, gas-impermeable plastics, and/or any other example material(s).

Additionally, in some examples, the liner 300 includes a valve (e.g., a one-way valve, a Schrader valve, etc.) to enable fluid to be provided in the fluid chamber 128 from an exterior of the liner 300 and/or the fluid spacer 124. In some examples, the fluid spacer 124 can have a pressure rating of approximately between 10 pounds per square inch and 40 pounds per square inch (e.g., 15 pounds per square inch). For example, the liner 300 can be hermetically sealed to ensure the fluid spacer 124 and/or the fluid remains securely enclosed within the fluid chamber 128 (e.g., to prevent leakage). In some examples, the liner 300 (e.g., a fluid bag) includes materials that provide an effective barrier against gas and/or liquid permeation. After the material of the liner 300 is selected, the liner is sealed to provide a hermetic bond. A hermetic bond can be provided by welding, fusion sealing (e.g., melting edges of the liner 300 together to create a hermetic bond), laser welding, electron beam welding, resistance welding, adhesive sealing (e.g., using epoxy resins to create a hermetic bond), using polytetrafluoroethylene (PTFE) sealing rings (e.g., O-rings) and/or any other sealing method(s). After the liner 300 is sealed, the liner 300 can be filled with fluid (e.g., a gas, a liquid, a solid, a gel, etc.). For example, gas can be introduced through a valve or port and the fluid chamber 128 is pressurized to a target pressure (e.g., 15 pounds per square inch (psi)). In some examples, for liquid (e.g., or incompressible fluids), volume controlled filling (e.g., maximum volume capacity filling) can be used based LGA shape variations (e.g., design envelopes, perimeter shapes, etc.) and/or other design parameters of the component stack 100 and/or IC package 106. In some such examples, the fluid spacer 124 and/or the fluid chamber 128 can be prefilled with a volume-controlled fluid amount, which can be determined based on IC warpage variance, performance testing, etc. After the fluid chamber 128 is filled, the valve can be sealed to ensure that the gas remains trapped inside the fluid chamber 128. In some examples, liquid can be introduced into a separate opening formed in the sealed liner 300 and the opening is sealed after filling the fluid chamber 128. After the fluid chamber 128 is filled, any remaining openings can be sealed using, for example, welding, adhesive bonding, seals, caps, and/or other closure structures or techniques. In some examples, the second liner 304 is formed first, hermetically sealed, and filled with a fluid. After, the first liner 302 can be coupled to the second liner 304 and sealed (e.g., hermetically sealed) to enclose the second liner 304 within the first liner 302.

The fluid chamber 128 of the example fluid spacer 124 of FIGS. 1 and 3A can have a fluid area that is substantially solid. In some examples, the fluid chamber 128 can have one or more cutout windows or openings to receive caps, fasteners, and/or any other fastener.

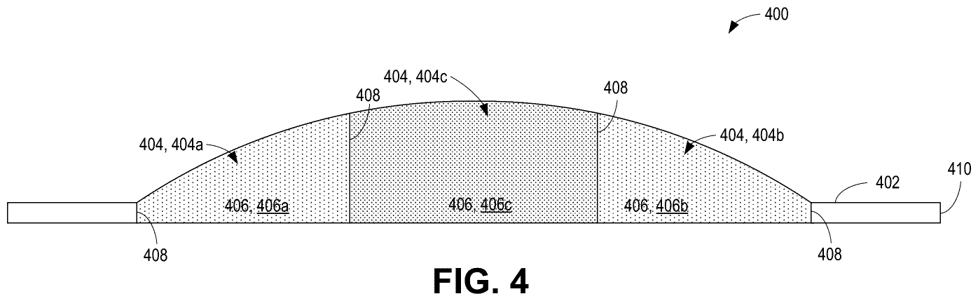

FIG. 4 is another example fluid spacer 400 disclosed herein that can implement the example component stack of FIG. 1. For example, the fluid spacer 400 can be provided in the component stack 100 of FIG. 1 in place of the fluid spacer 124 of FIG. 1. In the illustrated example, the fluid spacer 400 includes a flange 402 and a fluid chamber 404. The flange 402 is substantially similar to the flange 126 of FIG. 1. However, the fluid chamber 404 includes a plurality of chambers 404a-c. The chambers 404a-404c define respective ones of fluid compartments 406. In the illustrated example, a first fluid compartment 406a is fluidly isolated from a second fluid compartment 406b and/or a third fluid compartment 406c. In other words, the fluid compartments 406 are fluidly isolated or fluidly sealed relative to each other. Each of the fluid compartments 406 define dedicated or individual fluid chambers 404a-404c. To this end, the first fluid compartment 406a can include a first fluid, the second fluid compartment 406b can include a second fluid, the third fluid compartment 406c can include a third fluid, etc. The fluid spacer 400 of the illustrated example is a liner or bladder that includes a plurality of walls 408 for segregating or isolating respective ones of the fluid chambers 404a-404c. Each of the fluid chambers 404a-404c can be hermetically sealed to fluidly isolate a first fluid chamber 404a from a second fluid chamber 404b and/or a third fluid chamber 404c. In this manner, the fluid chambers 404a-c can each include different types of fluids. For example, a first fluid having a relatively low viscosity characteristic can be included in the first fluid chamber 404a and a second fluid chamber 404b (e.g., chambers adjacent a perimeter edge 410) of the fluid spacer 400 and a second fluid different from the first fluid having a high viscosity characteristic can be provided in the third fluid chamber 404c located at a center of the fluid spacer 400 and/or between the first fluid chamber 404a and the second fluid chamber 404b. In this manner, the fluid in the first fluid chamber 404a and the second fluid chamber 404b adjacent the perimeter edge can distribute a greater amount of force toward a center of the fluid spacer 400 and the fluid in the third fluid chamber 404c can be used to reduce vibration in addition to distributing the load from the perimeter edge 410 of the fluid spacer 400. In some examples, the fluids can be the same fluid in each of the fluid chambers 404 and that the compartmentalization of the fluid and/or the fluid chambers 404 is to control where the isolated portions of the fluid is able to move in response to pressure differentials across the respective compartments. This functionality, of course, could be combined with different types of fluids in the different compartments.

Although the fluid chamber 404 and/or the fluid compartments 406a-c are fluidly isolated, the fluid compartments 406 are flexible and/or deformable (e.g., elastically deformable). Therefore, forces can be distributed between different ones of the fluid compartments 406 when a stack load is applied to perimeter edges 410 of the fluid spacer 400. In the illustrated example, the fluid spacer 400 includes three distinct compartments. However, in some examples, the fluid spacer 400 can include two compartments, four compartments and/or any other number of fluid compartments 406 and/or fluid chambers 404.

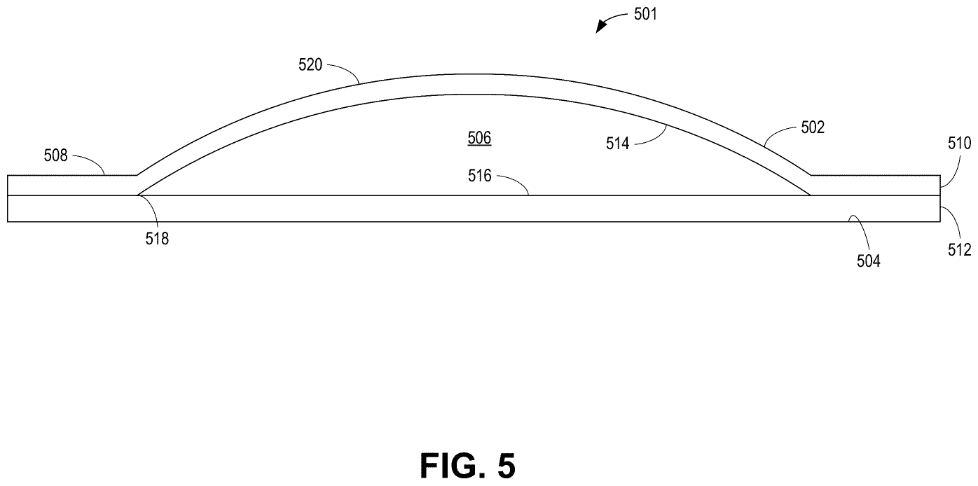

FIG. 5 is another example fluid spacer 501 disclosed herein. The fluid spacer of FIG. 5 includes a liner 502 that couples to a backplate 504 that can be used in a component stack. The backplate 504 of the illustrated example is substantially similar or identical to the backplate 114 of FIG. 1. Thus, the fluid spacer 501 can be provided in the component stack 100 of FIG. 1 in place of the fluid spacer 124 and the backplate 114 of FIG. 1.

The fluid spacer 501 of the illustrated example includes a fluid chamber 506 (e.g., a fluid-filled chamber) and a flange 508. The fluid chamber 506 of the illustrated example is defined by the liner 502 and the backplate 504. Specifically, a perimeter edge 510 of the liner 502 is coupled (e.g., attached) to a perimeter edge 512 of the backplate 504. The fluid chamber 506 of the illustrated example is defined by an inner surface 514 of the liner 502 and an upper surface 516 of the backplate 504 that is contained within an inner edge 518 of the flange 508 and oriented toward the liner 502. The fluid chamber 506 includes a fluid (e.g., the fluid 214). Thus, the fluid is positioned between the inner surface 514 (e.g., or walls) of the fluid chamber 506 and the upper surface 516 of the backplate 504 positioned within the inner edge 518 of the flange 508. In the illustrated example, the fluid chamber 506 can deform (e.g., elastically deform) to allow the fluid to move within the fluid chamber 506 in response to forces or pressures (e.g., stack loads) imparted to the fluid chamber 506. The fluid chamber 506 of the illustrated example defines a deformable, fixed volume chamber. In other words, the liner 502 is composed of a flexible material and can deform, deflect, and/or otherwise enable fluid within the fluid chamber 506 to move or shift in response to a force or pressure applied to an outer surface 520 of the liner 502 and/or the fluid chamber 506. The liner 502 can be coupled to the backplate 504 via welding (e.g., plastic welding), adhesive, compression seals, epoxy seals, and/or any other manufacturing process. In some examples, the liner 502 can be hermetically sealed with the backplate 504. In some examples, a seal can be positioned between the liner 502 (e.g., the flange 508) and the backplate 504.

The foregoing examples of the fluid spacers 124, 400, 501 can be used with any stackable or compressible IC package system. Although each example fluid spacer disclosed above have certain features, it should be understood that it is not necessary for a particular feature of one example to be used exclusively with that example. Instead, any of the features described above and/or depicted in the drawings can be combined with any of the examples, in addition to or in substitution for any of the other features of those examples. One example's features are not mutually exclusive to another example's features. Instead, the scope of this disclosure encompasses any combination of any of the features.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that provide fluid spacers (e.g., fluid-filled bodies, compressible bladders, compressible materials, etc.) to improve electrical connectivity for socket-based architectures. The fluid spacers (e.g., automatically) generate uniform pin load distribution, which will simplify component stack design and/or package corner shape(s) to distribute a pin load more evenly. Additionally or alternatively, examples disclosed herein reduce and/or eliminate fretting on pad surfaces in an associated IC package due to vibration risk caused by a side load because the fluid spacer (e.g., filled with a low viscous fluid) provides pressure to compensate low pin load location and reduce pin vertical movement. If constant pressure and pin load are maintained under vibration load, pin fretting damage can be reduced or eliminated.

Example 1 includes a component stack comprising an integrated circuit (IC) package, a circuit board, a socket to couple the IC package and the circuit board, a backplate coupled to the circuit board, a loading assembly to provide a stack load to the IC package, and a fluid liner positioned between the circuit board and the backplate.

Example 2 includes the component stack of example 1, wherein the fluid liner defines a fluid chamber to retain a fluid.

Example 3 includes the component stack of any one of examples 1-2, wherein the fluid is at least one of a gas or a liquid.

Example 4 includes the component stack of any one of examples 1-3, wherein the fluid liner is to distribute the stack load across an area of the IC package.

Example 5 includes the component stack of any one of examples 1-4, wherein the fluid is displaceable within the fluid chamber of the fluid liner in response to the stack load.

Example 6 includes the component stack of any one of examples 1-5, wherein the fluid liner further includes a flange.

Example 7 includes the component stack of any one of examples 1-6, wherein the flange includes a plurality of apertures spaced apart adjacent a perimeter of the flange.

Example 8 includes the component stack of any one of examples 1-7, wherein the apertures of the flange receive respective ones of guide pins of the backplate.

Example 9 includes the component stack of any one of examples 1-8, wherein the fluid liner includes a first liner and a second liner located within the first liner, the second liner defining the fluid chamber.

Example 10 includes the component stack of any one of examples 1-9, wherein the fluid chamber is to align with the IC package.

Example 11 includes the component stack of any one of examples 1-10, wherein the fluid automatically generates distributes a pin load in response to the stack load.

Example 12 includes the component stack of any one of examples 1-11, wherein the fluid liner has a first area that is greater than a second area of a pin array of the IC package.

Example 13 includes an apparatus comprising a backplate to be coupled to a circuit board opposite a socket for an IC package, a liner disposed between the backplate and the circuit board, and a fluid retained by the liner, the fluid to move within the liner in response to pressure differences between different portions of the backplate and corresponding different portions of the circuit board.

Example 14 includes the apparatus of example 13, further including a loading assembly to impart a stack load to the IC package, the fluid retained by the liner to distribute the stack load across the IC package.

Example 15 includes the apparatus of any one of examples 13-14, wherein the fluid provides a reactive load distributed across the circuit board between a perimeter edge and a center of the circuit board in response to the stack load imparted to the perimeter edge of the circuit board.

Example 16 includes the apparatus of any one of examples 13-15, wherein the liner is hermetically sealed with the backplate, at least a portion of the liner and at least a portion of the backplate to provide a fixed volume chamber to retain the fluid.

Example 17 includes the apparatus of any one of examples 13-16, wherein the fixed volume chamber is at least one of flexible or deformable.

Example 18 includes an apparatus comprising a circuit board, a backplate coupled to the circuit board, and a fluid bladder positioned between the circuit board and the backplate.

Example 19 includes the apparatus of example 18, wherein the fluid bladder is hermetically sealed.

Example 20 includes the apparatus of any one of examples 18-20, wherein the fluid bladder is to deform in response to pressure variations across the circuit board.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A component stack comprising:
an integrated circuit (IC) package;
a circuit board;
a socket to couple the IC package and the circuit board;
a backplate coupled to the circuit board;
a loading assembly to provide a stack load to the IC package; and
a fluid liner positioned between the circuit board and the backplate.

2. The component stack of claim 1, wherein the fluid liner defines a fluid chamber to retain a fluid.

3. The component stack of claim 2, wherein the fluid is a gas.

4. The component stack of claim 2, wherein the fluid liner is to distribute the stack load across an area of the IC package.

5. The component stack of claim 2, wherein the fluid is displaceable within the fluid chamber of the fluid liner in response to the stack load.

6. The component stack of claim 2, wherein the fluid liner includes a flange.

7. The component stack of claim 6, wherein the flange includes a plurality of apertures spaced apart adjacent a perimeter of the flange.

8. The component stack of claim 7, wherein the apertures of the flange receive respective ones of guide pins of the backplate.

9. The component stack of claim 6, wherein the fluid liner includes a first liner and a second liner located within the first liner, the second liner defining the fluid chamber.

10. The component stack of claim 2, wherein the fluid chamber is to align with the IC package.

11. The component stack of claim 2, wherein the fluid automatically redistributes a pin load in response to the stack load.

12. The component stack of claim 1, wherein the fluid liner has a first area that is greater than a second area of a pin array of the IC package.

13. An apparatus comprising:
a backplate to be coupled to a circuit board opposite a socket for an IC package;
a liner disposed between the backplate and the circuit board; and
a fluid retained by the liner, the fluid to move within the liner in response to pressure differences between different portions of the backplate and corresponding different portions of the circuit board.

14. The apparatus of claim 13, further including a loading assembly to impart a stack load to the IC package, the fluid retained by the liner to distribute the stack load across the IC package.

15. The apparatus of claim 14, wherein the fluid provides a reactive load distributed across the circuit board between a perimeter edge and a center of the circuit board in response to the stack load imparted to the perimeter edge of the circuit board.

16. The apparatus of claim 13, wherein the liner is hermetically sealed with the backplate, at least a portion of the liner and at least a portion of the backplate to provide a fixed volume chamber to retain the fluid.

17. The apparatus of claim 16, wherein the fixed volume chamber is at least one of flexible or deformable.

18. An apparatus comprising:
a circuit board;
a backplate coupled to the circuit board; and
a fluid bladder positioned between the circuit board and the backplate.

19. The apparatus of claim 18, wherein the fluid bladder is hermetically scaled.

20. The apparatus of claim 18. wherein the fluid bladder is to deform in response to pressure variations across the circuit board.
